(19) United States
(12) Patent Application Publication
(10) Pub. No.: US 2021/0272640 A1
(43) Pub. Date: Sep. 2, 2021

(54) SEMICONDUCTOR MEMORY DEVICE

(71) Applicant: KIOXIA CORPORATION, Tokyo (JP)

(72) Inventors: Tatsuo OGURA, Yokkaichi (JP); Takashi KURUSU, Yokkaichi (JP); Muneyuki TSUDA, Ichinomiya (JP); Hiroshi TAKEDA, Yokkaichi (JP); Nayuta KARIYA, Yokkaichi (JP)

(73) Assignee: KIOXIA CORPORATION, Tokyo (JP)

(21) Appl. No.: 17/014,776

(22) Filed: Sep. 8, 2020

(30) Foreign Application Priority Data
Feb. 28, 2020 (JP) 2020-032851

(51) Int. Cl. G11C 16/34; G11C 16/14; G11C 16/12; G11C 16/26; G11C 16/30; G11C 16/04

(52) U.S. Cl. CPC G11C 16/3472; G11C 16/14; G11C 16/0466; G11C 16/26; G11C 16/30; G11C 16/12

(57) ABSTRACT

A semiconductor memory device includes a plurality of conductive layers, a semiconductor layer opposed to the plurality of conductive layers, and an electric charge accumulation portion disposed between the semiconductor layer and the plurality of conductive layers. The electric charge accumulation portion includes a plurality of first electric charge accumulation portions opposed to the plurality of conductive layers, and a plurality of second electric charge accumulation portions disposed in positions different from the plurality of first electric charge accumulation portions. A distance between the first electric charge accumulation portion and the semiconductor layer is smaller than a distance between the second electric charge accumulation portion and the semiconductor layer. A distance between the second electric charge accumulation portion and the conductive layers is smaller than a distance between the first electric charge accumulation portion and the conductive layers.

### CROSS-REFERENCE TO RELATED APPLICATIONS

This application is based upon and claims the benefit of Japanese Patent Application No. 2020-032851, filed on Feb. 28, 2020, the entire contents of which are incorporated herein by reference.

### BACKGROUND

### Field

Embodiments described herein relate generally to a semiconductor memory device.

### Description of the Related Art

There has been known a semiconductor memory device that includes a substrate, a plurality of conductive layers, a semiconductor layer opposed to the plurality of conductive layers, and respective electric charge accumulation portions disposed between the semiconductor layer and the plurality of conductive layers.

### BRIEF DESCRIPTION OF THE DRAWINGS

FIG. 1 is an equivalent circuit diagram illustrating a schematic configuration of a semiconductor memory device according to a first embodiment;

FIG. 2 is a schematic perspective view of the semiconductor memory device;

FIG. 3 is an enlarged view of a part of FIG. 2;

FIG. 4 is an enlarged view of a part of FIG. 3;

FIG. 5 is a drawing illustrating a distribution of threshold voltages of memory cells MC;

FIG. 6 is a schematic cross-sectional view illustrating a state of trapped charge of a semiconductor memory device in a comparative example;

FIG. 7 is a schematic cross-sectional view illustrating a state of trapped charge of a semiconductor memory device in another comparative example;

FIG. 8 is a schematic cross-sectional view illustrating a state of trapped charge before data writing of the semiconductor memory device according to the first embodiment;

FIG. 9 is a flowchart illustrating an erase flow of the semiconductor memory device according to the first embodiment;

FIG. 10 is a waveform diagram illustrating applied voltages of respective portions in a flash erase operation of the same semiconductor memory device;

FIG. 11 is a schematic cross-sectional view illustrating a state of trapped charge after the flash erase operation of the same semiconductor memory device;

FIG. 12 is a waveform diagram illustrating applied voltages of the respective portions in a stripe erase operation to odd-numbered memory cells of the same semiconductor memory device;

FIG. 13 is a schematic cross-sectional view illustrating a state of trapped charge after the stripe erase operation to the odd-numbered memory cells of the same semiconductor memory device;

FIG. 14 is a waveform diagram illustrating applied voltages of the respective portions in a stripe erase operation to even-numbered memory cells of the same semiconductor memory device;

FIG. 15 is a schematic cross-sectional view illustrating a state of trapped charge after the stripe erase operation to the even-numbered memory cells of the same semiconductor memory device;

FIG. 16 is a flowchart illustrating a write flow of a semiconductor memory device according to a second embodiment;

FIG. 17 is a partial cross-sectional view for describing a manufacturing process of the semiconductor memory devices according to the first embodiment and the second embodiment;

FIG. 18 is a partial cross-sectional view for describing the manufacturing process of the semiconductor memory devices according to the first embodiment and the second embodiment;

FIG. 19 is a partial cross-sectional view for describing the manufacturing process of the semiconductor memory devices according to the first embodiment and the second embodiment;

FIG. 20 is a partial cross-sectional view for describing the manufacturing process of the semiconductor memory devices according to the first embodiment and the second embodiment;

FIG. 21 is a partial cross-sectional view for describing the manufacturing process of the semiconductor memory devices according to the first embodiment and the second embodiment;

FIG. 22 is a partial cross-sectional view for describing the manufacturing process of the semiconductor memory devices according to the first embodiment and the second embodiment;

FIG. 23 is a partial cross-sectional view for describing the manufacturing process of the semiconductor memory devices according to the first embodiment and the second embodiment;

FIG. 24 is a partial cross-sectional view for describing the manufacturing process of the semiconductor memory devices according to the first embodiment and the second embodiment;

FIG. 25 is a cross-sectional view of a part of a semiconductor memory device according to a third embodiment; and

FIG. 26 is a cross-sectional view of a part of a semiconductor memory device according to a fourth embodiment;

### DETAILED DESCRIPTION

A semiconductor memory device according to an embodiment includes: a substrate; and a memory cell array that includes a plurality of conductive layers, a semiconductor layer, and an electric charge accumulation portion, the plurality of conductive layers being disposed in a first direction intersecting with a main surface of the substrate, the semiconductor layer extending in the first direction and being opposed to the plurality of conductive layers, the electric charge accumulation portion being disposed between the semiconductor layer and the plurality of conductive layers, the memory cell array including a plurality of memory cells in positions where the plurality of conductive layers and the semiconductor layer are opposed, the plurality of memory cells being connected in series in the first direction to constitute a memory string, wherein the electric charge accumulation portion includes a plurality of first electric charge accumulation portions opposed to the respective plurality of conductive layers in a second direction along the main surface of the substrate, and a plurality of second electric charge accumulation portions disposed in positions different in the first direction and the second direction from the plurality of first electric charge accumulation portions, a distance in the second direction between a first electric charge accumulation portion of the plurality of first electric charge accumulation portions and the semiconductor layer is smaller than a distance in the second direction between a second electric charge accumulation portion of the plurality of second electric charge accumulation portions and the semiconductor layer, and a distance in the second direction between the second electric charge accumulation portion and the plurality of conductive layers is smaller than a distance in the second direction between the first electric charge accumulation portion and the plurality of conductive layers.

Next, semiconductor memory devices according to embodiments are described in detail with reference to the accompanying drawings. The following embodiments are only examples, and not described for the purpose of limiting the present invention. The following drawings are schematic, and for sake of convenient description, a part of configurations and the like are sometimes omitted. The same portions in a plurality of embodiments are attached by the same reference numerals and their descriptions may be omitted.

In this specification, a predetermined direction parallel to a surface (main surface) of the substrate is referred to as an X-direction, a direction parallel to the surface of the substrate and perpendicular to the X-direction is referred to as a Y-direction, and a direction perpendicular to the surface of the substrate is referred to as a Z-direction. Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion on the substrate side of this configuration. A top surface and an upper end of a certain configuration mean a surface and an end portion on a side opposite to the substrate of this configuration.

In this specification, a “semiconductor memory device” includes various kinds of meanings, such as a memory system including a control die, such as a memory die, a memory chip, a memory card, and an SSD, and a configuration including a host computer, such as a smartphone, a tablet terminal, and a personal computer.

In this specification, a first configuration “being electrically connected” to a second configuration refers that the first configuration is connected to the second configuration directly or via wiring, a semiconductor member, or a circuit, such as a transistor. For example, when three transistors are connected in series, even when the 2nd transistor is in OFF state, the 1st transistor is “electrically connected” to the 3rd transistor.

### First Embodiment

[Configuration]

A configuration of a semiconductor memory device according to a first embodiment is described with reference to the drawings below.

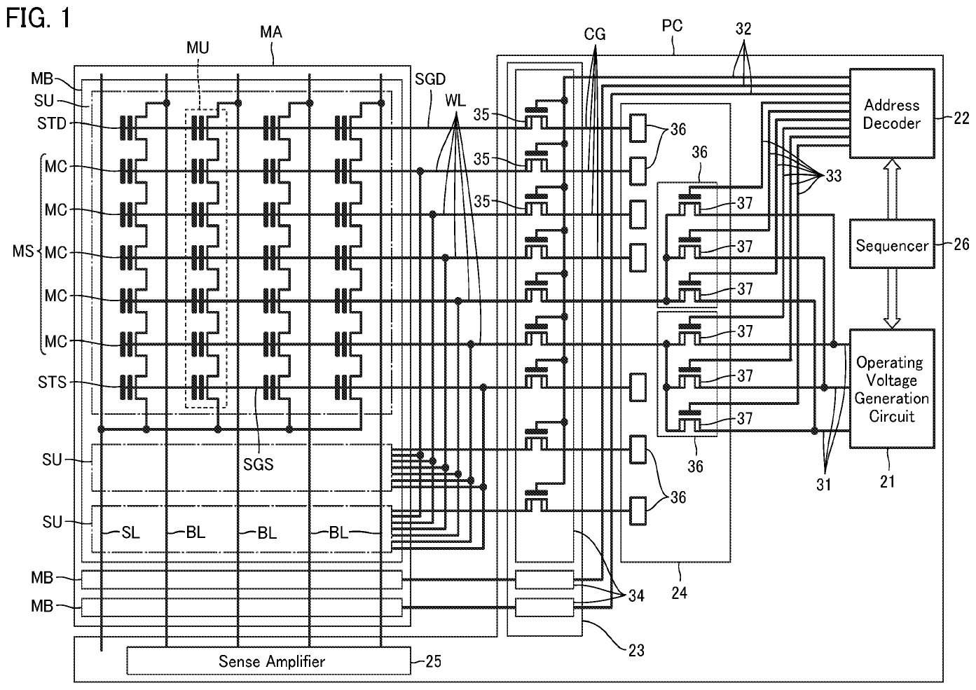

FIG. 1 is an equivalent circuit diagram schematically illustrating the configuration of the semiconductor memory device according to the first embodiment.

The semiconductor memory device according to the embodiment includes a memory cell array MA and a peripheral circuit PC as a control circuit controlling the memory cell array MA.

The memory cell array MA includes a plurality of memory blocks MB. The plurality of memory blocks MB each include a plurality of string units SU. The plurality of string units SU each include a plurality of memory units MU. The plurality of memory units MU have one ends each connected to the peripheral circuit PC via a bit line BL. The plurality of memory units MU have other ends each connected to the peripheral circuit PC via a common source line SL.

The memory units MU includes a drain select transistor STD, a plurality of memory cells MC (memory string MS), and a source select transistor STS, which are connected in series between the bit lines BL and the source line SL. Hereinafter, the drain select transistor STD and the source select transistor STS may be simply referred to as the select transistors (STD, STS) and the like.

The memory cell MC is a field-effect type transistor (memory transistor) including a semiconductor layer that functions as a channel region, a gate insulating film including an electric charge accumulation film, and a gate electrode. The memory cell MC has a threshold voltage that varies corresponding to an electric charge amount in the electric charge accumulation film. The respective gate electrodes of the plurality of memory cells MC corresponding to one memory string MS are connected to word lines WL. These respective word lines WL are commonly connected to all the memory strings MS in one memory block MB.

The select transistor (STD, STS) is a field-effect type transistor including a semiconductor layer that functions as a channel region, a gate insulating film, and a gate electrode. The respective gate electrodes of the select transistors (STD, STS) are connected to select gate lines (SGD, SGS). The drain select gate line SGD is disposed corresponding to the string unit SU and commonly connected to all the memory units MU in one string unit SU. The source select gate line SGS is commonly connected to all the memory units MU in the plurality of string units SU in one memory block MB.

The peripheral circuit PC includes an operating voltage generation circuit 21 that generates operating voltages, an address decoder 22 that decodes address data, a block select circuit 23 and a voltage select circuit 24 that transfer the operating voltage to the memory cell array MA according to an output signal of the address decoder 22, a sense amplifier 25 connected to the bit lines BL, and a sequencer 26 that controls them.

The operating voltage generation circuit 21 sequentially generates a plurality of operating voltages applied to the bit line BL, the source line SL, the word line WL, and the select gate lines (SGD, SGS) in a read operation, a write operation, and an erase operation for the memory cell array MA, in response to a control signal from the sequencer 26 to output the operating voltages to the plurality of operating voltage output terminals 31. The operating voltage generation circuit 21 includes, for example, a plurality of charge pump circuits and a plurality of regulator circuits.

The address decoder 22 includes a plurality of block select lines 32 and a plurality of voltage select lines 33. For example, the address decoder 22 sequentially refers to address data of an address register in response to the control signal from the sequencer 26, decodes this address data to cause the predetermined block select line 32 and voltage select line 33 corresponding to the address data to be in a state of “H,” and cause the block select line 32 and the voltage select line 33 other than the above to be in a state of “L.”

The block select circuit 23 includes a plurality of block selectors 34 that correspond to the memory blocks MB. The plurality of block selectors 34 each include a plurality of block select transistors 35 corresponding to the word lines WL and the select gate lines (SGD, SGS). The block select transistor 35 is, for example, a field-effect type high voltage transistor. The block select transistors 35 have one ends each electrically connected to the corresponding word line WL or the select gate line (SGD, SGS). Other ends are each electrically connected to the operating voltage output terminal 31 via a wiring CG and the voltage select circuit 24. The gate electrodes are commonly connected to the corresponding block select line 32.

The voltage select circuit 24 includes a plurality of voltage selectors 36 corresponding to the word lines WL and the select gate lines (SGD, SGS). The plurality of voltage selectors 36 each includes a plurality of voltage select transistors 37. The voltage select transistor 37 is, for example, a field-effect type high voltage transistor. The voltage select transistors 37 have one ends each electrically connected to the corresponding word line WL or the select gate line (SGD, SGS) via the wiring CG and the block select circuit 23. Other ends are each electrically connected to the corresponding operating voltage output terminal 31. The gate electrodes are each connected to the corresponding voltage select line 33.

The sense amplifier 25 is connected to the plurality of bit lines BL. The sense amplifier 25 includes, for example, a plurality of sense amplifier units corresponding to the bit lines BL. The sense amplifier units each include a clamp transistor that charges the bit line BL based on the voltage generated in the operating voltage generation circuit 21, a sense circuit that senses the voltage or a current of the bit line BL, a plurality of latches that hold output signals, write data, verify pass flags FLG and the like of this sense circuit, and a logic circuit. The logic circuit identifies data held in the memory cell MC by referring to data on a lower page held by the latch in, for example, the read operation. The logic circuit controls the voltage of the bit line BL by referring to data on a lower page held by the latch in, for example, the write operation.

The sequencer 26 outputs the control signal to the operating voltage generation circuit 21, the address decoder 22, and the sense amplifier 25, according to an input instruction and a state of the semiconductor memory device. For example, the sequencer 26 sequentially refers to command data of a command register in response to a clock signal, decodes this command data, and outputs it to the operating voltage generation circuit 21, the address decoder 22, and the sense amplifier 25.

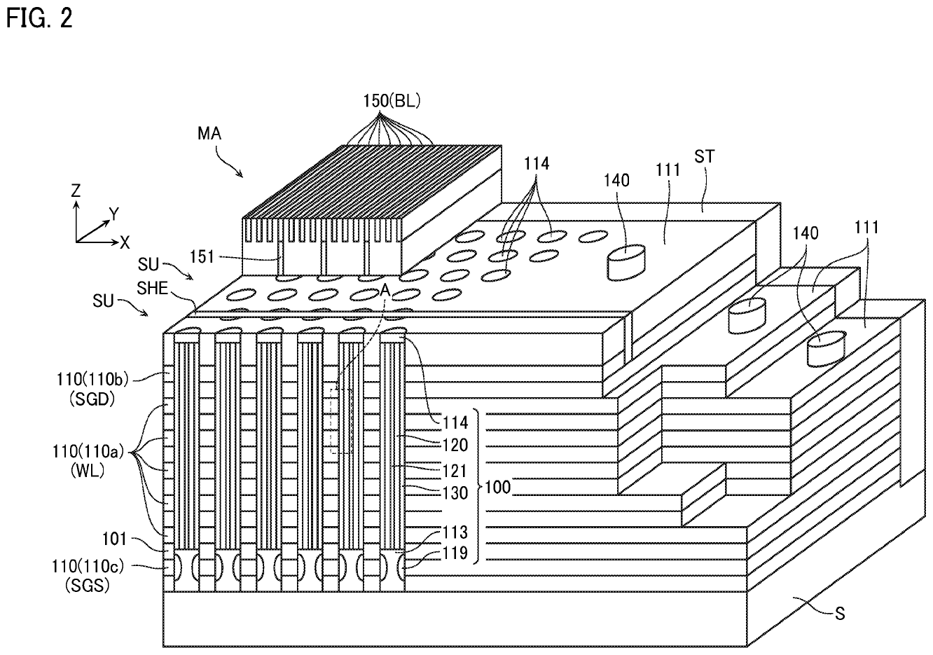

FIG. 2 is a schematic perspective view of the semiconductor memory device according to the embodiment. For sake of convenient description, a part of the configuration is omitted in FIG. 2.

As illustrated in FIG. 2, the semiconductor memory device according to the embodiment includes a substrate S, and the memory cell array MA disposed above the substrate S.

The substrate S is a semiconductor substrate made of, for example, single-crystal silicon (Si). The substrate S has a double well structure that includes, for example, an N-type impurity layer of phosphorus (P) and the like on a surface of a semiconductor substrate and further a P-type impurity layer of boron (B) and the like in this N-type impurity layer. In the embodiment, the surface of the substrate S is a wiring layer that functions as a lower wiring. However, a wiring layer may be additionally disposed above the substrate S.

The memory cell array MA includes a plurality of memory structures 100 in, for example, a columnar shape extending in the Z direction, a plurality of conductive layers 110 in a plate shape extending in, for example, XY direction that cover outer peripheral surfaces of the plurality of memory structures 100 on the X-Y cross-sectional surface, contacts 140 connected to the plurality of conductive layers 110, and a plurality of wirings 150 connected to upper ends of the memory structures 100.

The memory structures 100 are disposed in a predetermined pattern in the X direction and the Y direction. These memory structures 100 basically function as the memory units MU. The memory cells MC are disposed on respective intersecting portions between the memory structures 100 and the conductive layers 110.

The memory structure 100 includes a semiconductor layer 120 extending in the Z direction, a gate insulating film 130 disposed between the semiconductor layer 120 and the conductive layers 110, a semiconductor layer 113 connected between a lower end of the semiconductor layer 120 and the surface of the substrate S, and a semiconductor layer 114 connected to an upper end of the semiconductor layer 120.

For example, the semiconductor layer 120 functions as a channel region of the plurality of memory cells MC and the drain select transistor STD included in one memory unit MU (FIG. 1). The semiconductor layer 120 has, for example, an approximately cylindrical shape and has the center part into which an insulating layer 121, such as silicon oxide (SiO₂), is embedded. The semiconductor layer 120 includes, for example, a semiconductor, such as non-doped polycrystalline silicon (Si).

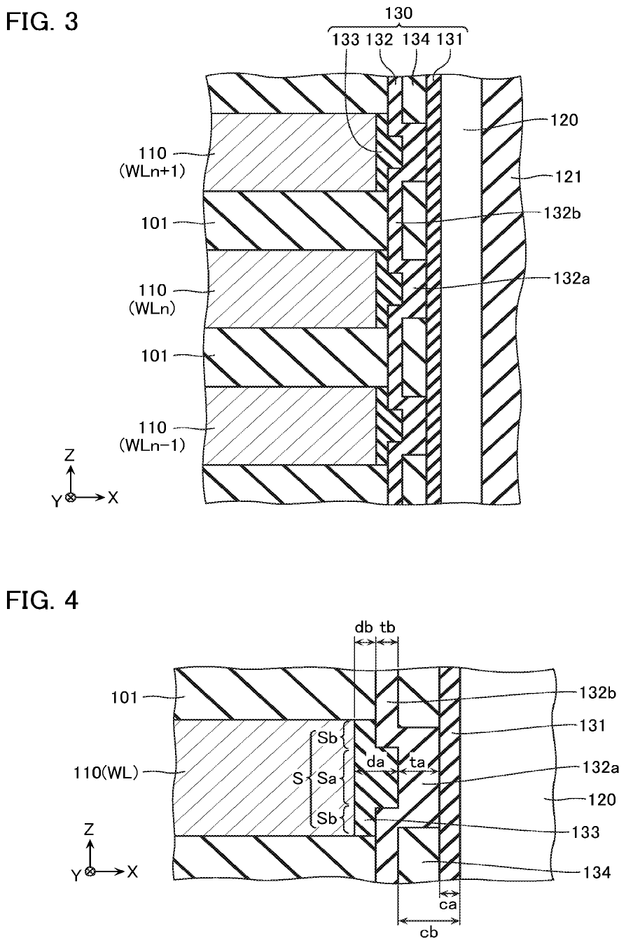

The gate insulating film 130 is disposed on an outer peripheral surface of the semiconductor layer 120 and in an approximately cylindrical shape. FIG. 3 is a cross-sectional view enlarging an A part in FIG. 2, and FIG. 4 is a cross-sectional view further enlarging a part of it. For example, as illustrated in FIG. 3, the gate insulating film 130 includes a tunnel insulating film 131, an electric charge accumulation film 132, and block insulating films 133, 134 stacked between the semiconductor layer 120 and the conductive layer 110. The tunnel insulating film 131 and the block insulating films 133, 134 are insulating layers of, for example, silicon oxide (SiO₂). The electric charge accumulation film 132 is a film that can accumulate electric charge, such as silicon nitride (SiN). Note that while FIG. 3 and FIG. 4 illustrate a configuration on a cross-sectional surface (X-Z cross-sectional surface) along the X direction of a part of the memory unit MU, the memory unit MU includes a similar configuration even on a cross-sectional surface along a main surface direction of the substrate S other than the X direction. While the configuration of the embodiment is continuously described below with, for example, the X direction as the main surface direction of the substrate S, cross-sectional structures in other directions along the main surface of the substrate S are also similarly understood.

The electric charge accumulation film 132 includes a first electric charge accumulation portion 132a disposed in a portion opposed in the X direction to the conductive layers 110 and a second electric charge accumulation portion 132b disposed in a position different in the X direction and the Z direction from this first electric charge accumulation portion 132a. In this example, the electric charge accumulation film 132 has a whole body extending in the Z direction, and only portions (the first electric charge accumulation portions 132a) opposed to the conductive layers 110 project to a side of the semiconductor layer 120 to be formed to have a zigzag shape.

As illustrated in detail in FIG. 4, a distance ca in the X direction between the first electric charge accumulation portion 132a and the semiconductor layer 120 is smaller than a distance cb in the X direction between the second electric charge accumulation portion 132b and the semiconductor layer 120. A distance db in the X direction between the second electric charge accumulation portion 132b and the conductive layer 110 is smaller than a distance da in the X direction between the first electric charge accumulation portion 132a and the conductive layer 110. Surface portions Sb adjacent to both ends in the Z direction in an opposed surface S to the electric charge accumulation film 132 of the conductive layer 110 is opposed in the X direction to the second electric charge accumulation portion 132b. A surface portion Sa inside with respect to the surface portions Sb adjacent to both the ends in the opposed surface S is opposed in the X direction to the first electric charge accumulation portion 132a. The second electric charge accumulation portion 132b extends in the Z direction so as to extend beyond positions opposed to both the ends in the Z direction of the opposed surface S of the conductive layer 110 from positions opposed to the surface portions Sb of the conductive layer 110. More specifically, the second electric charge accumulation portion 132b extends in the Z direction beyond the positions opposed to both the ends in the Z direction of the opposed surface S of the conductive layer 110 so as not to be opposed to an opposed surface portion in the Z direction, which is opposed to adjacent another conductive layer 110 in the Z direction, of the conductive layer 110 in a portion outside of the position opposed to the surface portions Sb adjacent to both the ends of the conductive layer 110. A width to in the X direction of the first electric charge accumulation portion 132a is greater than a width tb in the X direction of the second electric charge accumulation portion 132b. That is, the opposed surface S to the electric charge accumulation film 132 of the word line WL has a center portion in the Z direction (a stacking direction) opposed to the first electric charge accumulation portion 132a and both end portions in the Z direction opposed to the second electric charge accumulation portion 132b. In this example, a length in the Z direction of the first electric charge accumulation portion 132a is smaller than a thickness in the Z direction of the conductive layer 110.

Returning to FIG. 2, the semiconductor layer 113 functions as, for example, a channel region of the source select transistor STS. The semiconductor layer 113 has outer peripheral surfaces on which gate insulating films 119 are disposed. The semiconductor layer 113 includes a semiconductor, such as single-crystal silicon (Si). The gate insulating film 119 is an insulating film of, for example, silicon oxide (SiO₂).

The semiconductor layer 114 is a layer that includes N type impurities, such as phosphorus, within the semiconductor, such as polycrystalline silicon (Si).

The plurality of conductive layers 110 are arranged in the Z direction via insulating layers 101 of, for example, silicon oxide (SiO₂) and have an approximately plate shape that extends in the X direction and the Y direction. The conductive layers 110 have a plurality of through-holes formed in a predetermined pattern, and the respective memory structures 100 are disposed inside the through-holes. The conductive layers 110 have end portions in the X direction where contact portions 111 connected to the contacts 140 are disposed. Since the conductive layer 110 constitutes the memory block MB, the conductive layer 110 is separated in the Y direction by an insulating portion ST of, for example, silicon oxide extending to the substrate S in the X direction and the Z direction. The conductive layer 110 includes a stacked film and the like of, for example, titanium nitride (TiN) and tungsten (W).

Conductive layers 110a among the conductive layers 110 function as the word lines WL (FIG. 1) and gate electrodes of the plurality of memory cells MC (FIG. 1) connected to the word lines WL.

A conductive layer 110b disposed thereabove functions as the drain select gate line SGD (FIG. 1) and gate electrodes of the plurality of drain select transistors STD (FIG. 1) connected to the drain select gate line SGD. The conductive layer 110b among the conductive layers 110 separated by the insulating portion ST is further separated in the Y direction by an insulating portion SHE of, for example, silicon oxide extending in the X direction and the Z direction. That is, the conductive layer 110b has a width in the Y direction smaller than that of the conductive layer 110a.

A conductive layer 110c disposed therebelow functions as the source select gate line SGS (FIG. 1) and gate electrodes of the plurality of source select transistors STS connected to the source select gate line SGS. The conductive layer 110c covers the outer peripheral surface of the semiconductor layer 113 via the gate insulating film 119.

The contacts 140 extend in the Z direction and are connected to the contact portions 111 of the plurality of conductive layers 110. The contact 140 includes a stacked film and the like of, for example, titanium nitride (TiN) and tungsten (W).

The wiring 150 functions as the bit line BL. The plurality of wirings 150 are arranged in the X direction and extend in the Y direction. The wirings 150 are connected to the plurality of memory structures 100 via contacts 151.

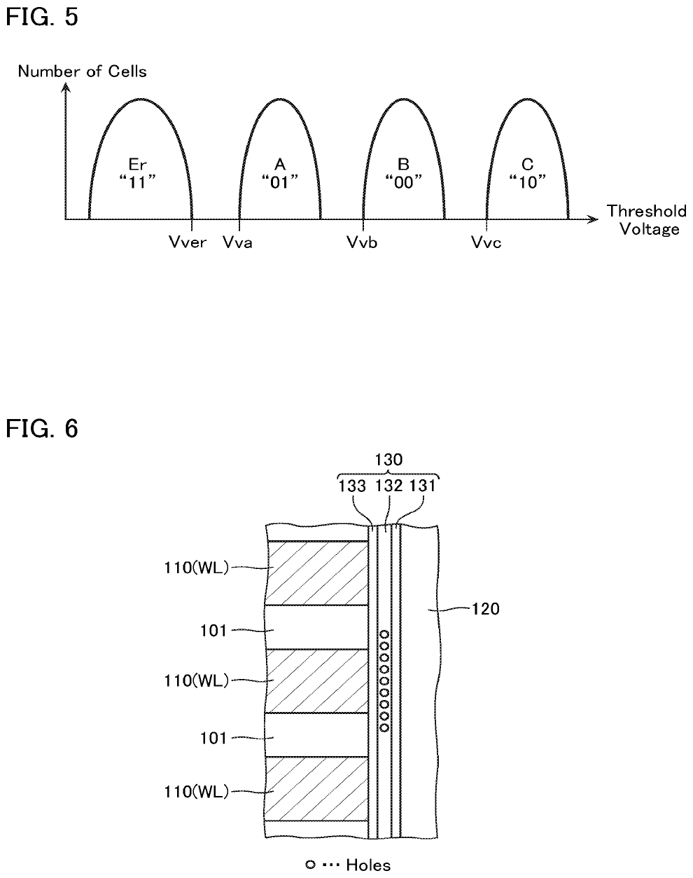

Next, the threshold voltage of the memory cell MC is described. FIG. 5 is a drawing illustrating a relationship between the threshold voltage of the memory cell MC and the number of cells. When a write operation is performed on the memory cell MC, the threshold voltage of the memory cell MC depends on an amount of the electrons or the holes accumulated on the electric charge accumulation film 132 of the memory cell MC. In this example, four patterns of threshold distributions are formed. Distributions Er, A, B, and C are formed in the order from lower threshold voltage, and the memory cells MC corresponding to the distributions are assigned with, for example, data “11,” “01,” “00,” and “10.” The distribution Er has a threshold level at the lowest erase level, and the holes are accumulated on the electric charge accumulation film 132. The distributions A, B, and C are formed in the order from smaller number of the electrons held on the electric charge accumulation film 132 below. Note that these distributions are also hereinafter referred to as levels Er, A, B, and C. A voltage Vver, which is the maximum value of the threshold voltage of the level Er, indicates an erase verify voltage in the erase operation, and voltages Vva, Vvb, and Vvc, which are the minimum values of the threshold voltages of the levels A, B, and C, indicate program verify voltages in write operations of the levels A, B, and C, respectively. The erase verify voltage Vver is a negative voltage lower than 0 V. The program verify voltages Vva, Vvb, and Vvc are positive voltages greater than 0 V.

[Operation]

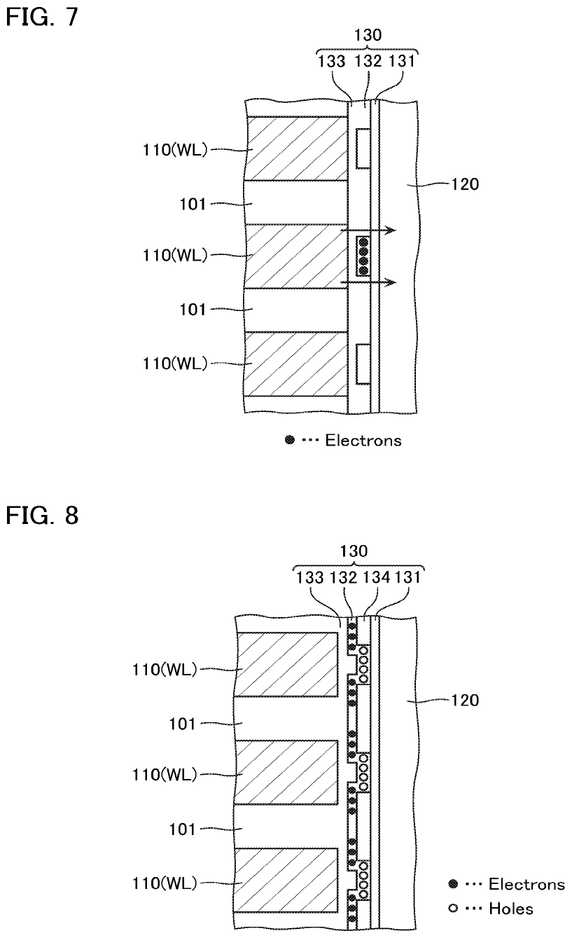

Next, comparative examples are described with reference to FIG. 6 and FIG. 7 prior to a description of a data erase operation of the memory cell MC of the semiconductor memory device thus configured.

FIG. 6 and FIG. 7 schematically illustrate a part of cross-sectional surfaces of semiconductor memory devices in a comparative example and another comparative example together with states of trapped charge. Specifically, FIG. 6 is a semiconductor memory device formed such that the electric charge accumulation film 132 extends in the Z direction. Thus, when the electric charge accumulation film 132 has a consecutive structure in the Z direction, an influence between the adjacent memory cells MC increases in association with decreased pitches between the memory cells MC. Specifically, it is possible to generate problems, such as a leakage of charge to the adjacent memory cell MC by Neighbor Word-line Interference (NWI), unwanted charge movement via the electric charge accumulation film 132 between the adjacent memory cells MC by High Temperature Data Retention (HTDR), and a deterioration in data retention characteristics by hole injection between the adjacent memory cells MC.

Therefore, as illustrated in FIG. 7, a structure that separates the electric charge accumulation film 132 for each memory cell MC can be considered. However, the structure in which the electric charge accumulation film 132 thus separated for each memory cell MC tends to shorten a length in a gate length direction of the portion where the electrons are accumulated when the data is written and to turn the channel on via the portion where the electric charge accumulation film 132 does not exist as illustrated when the data is read. That is, an effective gate length shortens. When the effective gate length shortens, the noise increases, and a reduction in a margin between the threshold distributions is caused when multi-valued data, such as Quadruple-Level Cell (QLC), is stored. As the result, the read error possibly increases. This problem significantly appears in data in the side where the threshold distribution is high.

Next, the data erase operation of the memory cell MC of the semiconductor memory device according to the embodiment is described. First, FIG. 8 schematically illustrates a state of trapped charge before the data writing of the semiconductor memory device according to the embodiment.

In the embodiment, as illustrated in FIG. 8, the first electric charge accumulation portion 132a, which is opposed to the center portion in the Z direction of the opposed surface to the electric charge accumulation film 132 of the conductive layer 110, has a structure of projecting to the semiconductor layer 120 side. The second electric charge accumulation portion 132b, which is opposed to the vicinity of both the ends in the Z direction of the conductive layer 110, is structured to be shifted to the conductive layer 110 side with respect to the first electric charge accumulation portion 132a, and further extending in the Z direction so as to extend beyond both the ends of the conductive layer 110. In such a structure, the second electric charge accumulation portion 132b is preliminarily accumulated with the electrons. This shields the electric field between the vicinity of both the ends in the Z direction of the word line WL and the channels by the electrons accumulated in the second electric charge accumulation portion 132b when the data is read. As the result, it is possible to restrain the channels from being turned to a normally on state at both the sides in the gate length direction of the first electric charge accumulation portion 132a. This can restrain the effective gate length of the memory cell MC from being shortened while imitating the divided structure of the electric charge accumulation film 132 in the embodiment. Note that since the distance cb in the X direction between the second electric charge accumulation portion 132b and the semiconductor layer 120 is greater than the distance ca in the X direction between the first electric charge accumulation portion 132a and the semiconductor layer 120, even though the second electric charge accumulation portion 132b is accumulated with the electrons for shielding, it is possible to reduce the influence of the accumulated electrons on the threshold of the memory cell MC.

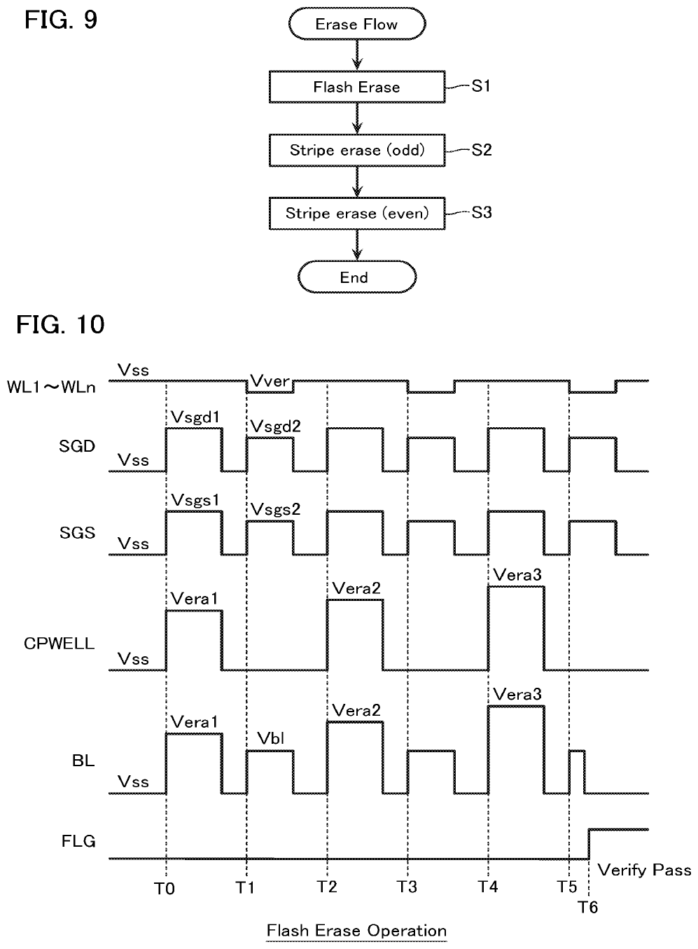

FIG. 9 is a flowchart illustrating an erase flow for generating a state of trapped charge of the electric charge accumulation film 132 as illustrated in FIG. 8. This erase flow executes a flash erase operation (S1) that collectively erases the memory block MB, a stripe erase operation (S2) with respect to odd-numbered memory cells MC-odd in the memory unit MU, and a stripe erase operation (S3) with respect to even-numbered memory cells MC-even in the memory unit MU in this order.

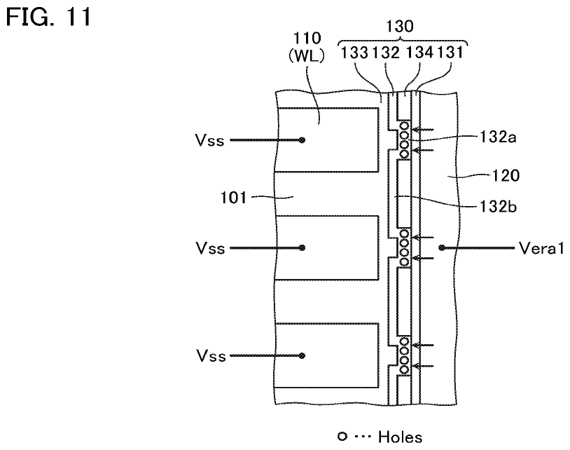

FIG. 10 is a waveform diagram illustrating the flash erase operation (S1). FIG. 11 schematically illustrates a state of the trapped charge of the electric charge accumulation film 132 after this flash erase operation (S1).

At a time T0 illustrated in FIG. 10, a voltage Vss is applied to all the word lines WL1 to WLn. An erase voltage Vera1 is applied to contacts connected to the bit line BL and a well wiring CPWELL (not illustrated). A voltage Vsgd1, which is a degree where a Gate Induced Drain Leakage (GIDL) current is generated in the select transistor STD, is applied to the select gate line SGD, and a voltage Vsgs1, which turns on the select transistor STS to ensure injection of the holes from a side of the substrate S, is applied to the select gate line SGS. This injects the holes from the substrate S side and a side of the bit line BL into the channel formed on the semiconductor layer 120. As illustrated in FIG. 11, the holes are injected into the first electric charge accumulation portion 132a of the electric charge accumulation film 132 opposed to all the word lines WL1 to WLn via the tunnel insulating film 131. From a subsequent time T1, the erase verify operation starts. The erase verify voltage Vver slightly smaller than the voltage Vss is provided to every word line WL. A predetermined bit line voltage Vbl is applied to the bit line BL, voltages Vsgd2 and Vsgs2, which turn on the select transistors STD and STS, respectively, are applied to the select gate lines SGD and SGS. If it is not a verify pass, the bit line voltage Vbl is maintained. In this case, at a time T2, the flash erase operation is performed for the second time. That is, the Vss is applied to all the word lines WL1 to WLn. An erase voltage Vera2 slightly larger than the erase voltage Vera1 is applied to the bit line BL and the well wiring CPWELL. The erase verify operation similar to above is executed at a subsequent time T3 as well. At times T4 and T5, the erase operation and the erase verify operation are performed for the third time, and when the verification passes at a time T6, a verify pass flag FLG is launched to terminate the flash erase operation.

Executing this flash erase operation (S1) accumulates the holes injected from the channel side since the first electric charge accumulation portion 132a is close to the channel formed on the semiconductor layer 120 as illustrated in FIG. 11. In view of this, the threshold level is reduced to the erase level (Er). Meanwhile, the second electric charge accumulation portion 132b is difficult for the holes to move from the channel since it is farther from the semiconductor layer 120 than the first electric charge accumulation portion 132a.

Subsequently, a stripe erase operation (S2) with respect to the odd-numbered memory cells MC-odd is executed.

Note that in the embodiment, the odd-numbered word lines WL-odd counted from the bottom correspond to “first conductive layers” and the even-numbered word lines WL-even counted from the bottom correspond to “second conductive layers” in the stripe erase operation executed as described below. However, this correspondence relationship is one example, and it is possible to correspond the word lines WL-even to the “first conductive layers,” and the word lines WL-odd to the “second conductive layers.”

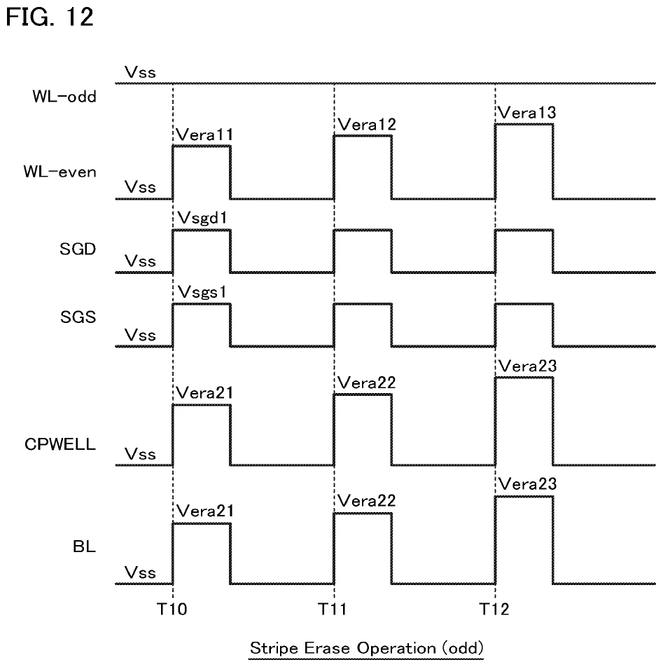

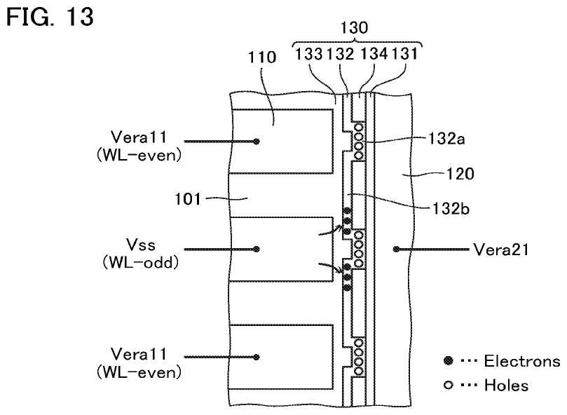

FIG. 12 is a waveform diagram illustrating the stripe erase operation (S2) with respect to the odd-numbered memory cells MC-odd. FIG. 13 schematically illustrates a state of the trapped charge of the electric charge accumulation film 132 after this stripe erase operation (S2).

The Vss as the first voltage, for example, 0 V, is applied to the odd-numbered word lines WL-odd, and a voltage Vera11 is applied to the even-numbered word lines WL-even at a time T10. An erase voltage Vera21 is applied to the contacts connected to the bit line BL and the well wiring CPWELL (not illustrated). The voltage Vera11 may be set smaller than the erase voltage Vera21. This is because the holes of the first electric charge accumulation portion 132a do not move to the channel side. The voltage Vsgd1, which ensures turning on the select transistor STD, is applied to the select gate line SGD, and the voltage Vsgs1, which ensures turning on the select transistor STS, is applied to the select gate line SGS. This causes the channel formed on the semiconductor layer 120 to be set to the erase voltage Vera21. As illustrated in FIG. 13, an electric field formed between the odd-numbered word lines WL-odd and the even-numbered word lines WL-even adjacent to these injects the electrons into the second electric charge accumulation portion 132b close to the odd-numbered word lines WL-odd via the block insulating film 133. Meanwhile, since the block insulating film 133 from the odd-numbered word line WL-odd to the first electric charge accumulation portion 132a opposed to this is thick, the electrons are not injected into the first electric charge accumulation portion 132a from the word line WL-odd side.

At a subsequent time T11, a voltage Vera12 and an erase voltage Vera22 are set slightly larger than the voltage Vera11 and the erase voltage Vera21 for the first time, respectively, and the stripe erase operation for the second time is executed. Furthermore, at a time T12, a voltage Vera13 and an erase voltage Vera23 are set slightly larger than the voltage Vera12 and the erase voltage Vera22 for the second time, respectively, and the stripe erase operation for the third time is executed. After the stripe erase operation is executed for the predetermined number of times, the stripe erase operation (S2) with respect to the odd-numbered memory cells MC-odd is terminated.

When the stripe erase operation (S2) with respect to the odd-numbered memory cells MC-odd is terminated, as illustrated in FIG. 13, a predetermined amount of the electrons is accumulated in portions close to the word lines WL-odd of the second electric charge accumulation portions 132b.

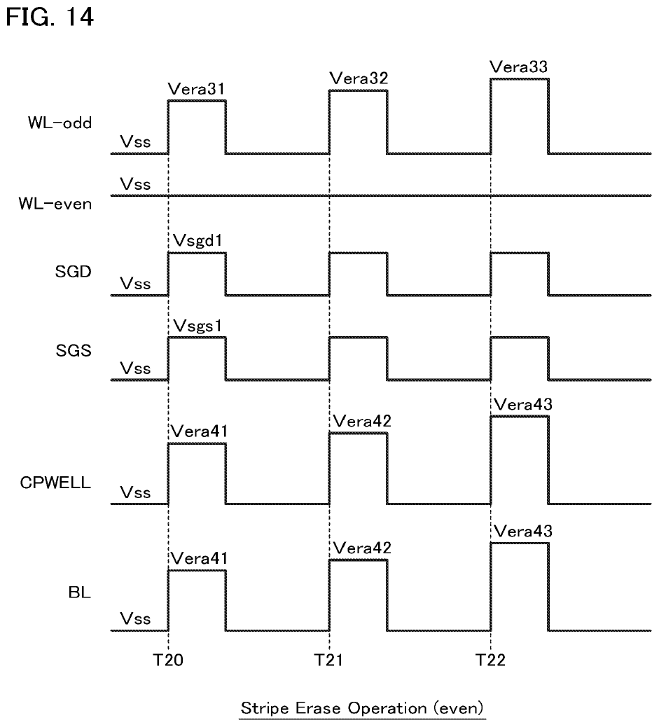

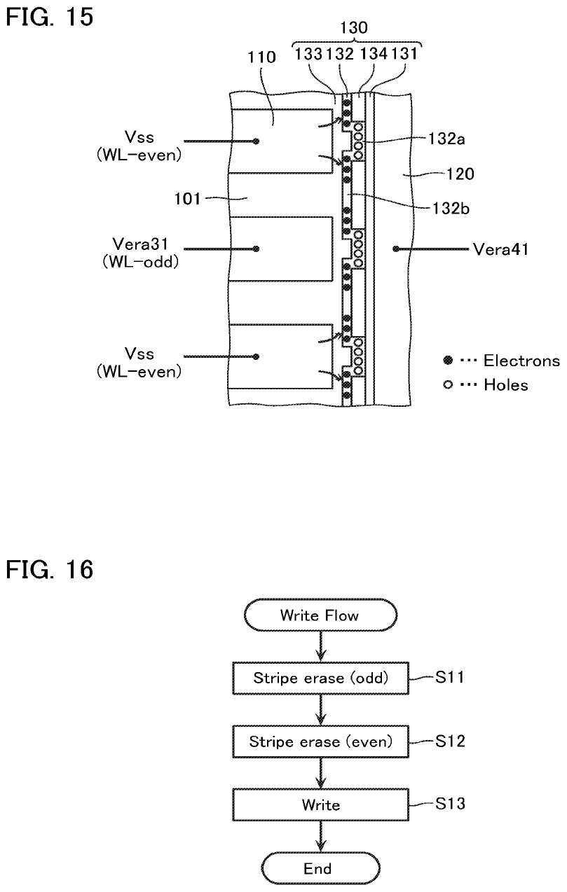

FIG. 14 is a waveform diagram illustrating the stripe erase operation (S3) with respect to the even-numbered memory cells MC-even. FIG. 15 schematically illustrates a state of the trapped charge of the electric charge accumulation film 132 after this stripe erase operation (S3).

At a time T20, the Vss as the first voltage, for example, 0 V, is applied to the even-numbered word lines WL-even, and a voltage Vera31 is applied to the odd-numbered word lines WL-odd. An erase voltage Vera41 is applied to the contacts connected to the bit line BL and the well wiring CPWELL (not illustrated). The voltage Vera31 may be set smaller than the erase voltage Vera41. This is because the holes of the first electric charge accumulation portion 132a do not move to the channel side. The voltage Vsgd1, which ensures turning on the select transistor STD, is applied to the select gate line SGD, and the voltage Vsgs1, which ensures turning on the select transistor STS, is applied to the select gate line SGS. This causes the channel formed on the semiconductor layer 120 to be set to the erase voltage Vera41. As illustrated in FIG. 15, an electric field formed between the even-numbered word line WL-even and the odd-numbered word line WL-odd adjacent to this injects the electrons into the second electric charge accumulation portion 132b close to the even-numbered word line WL-even via the block insulating film 133. Meanwhile, since the block insulating film 133 from the even-numbered word line WL-even to the first electric charge accumulation portion 132a opposed to this is thick, the electrons are not injected into the first electric charge accumulation portion 132a from the word line WL-even side.

At a subsequent time T21, a voltage Vera32 and an erase voltage Vera42 are set slightly larger than the voltage Vera31 and the erase voltage Vera41 for the first time, respectively, and the stripe erase operation for the second time is executed. Furthermore, at a time T22, a voltage Vera33 and an erase voltage Vera43 are set slightly larger than the voltage Vera32 and the erase voltage Vera42 for the second time, respectively, and the stripe erase operation for the third time is executed. After the stripe erase operation is executed for a predetermined number of times, the stripe erase operation (S3) with respect to the even-numbered memory cells MC-even is terminated.

When the stripe erase operation (S3) with respect to the even-numbered memory cells MC-even is terminated, as illustrated in FIG. 15, a predetermined amount of the electrons is accumulated in portions close to the word lines WL-even of the second electric charge accumulation portions 132b.

Data writing to the memory cell MC after such an erase flow is executed is performed as follows.

A program voltage Vprog is applied to a selected word line WL-sel, and a voltage Vpass lower than the program voltage Vprog is applied to a non-selected word line WL-usel. In the semiconductor layer 120 side, the Vss is applied via the bit line BL when the data is written (when the threshold is moved), and a voltage larger than the Vss is applied when the data (the threshold) is maintained. As the result, in the memory cell MC into which the data is written, the electrons are injected into the first electric charge accumulation portion 132a via the tunnel insulating film 131 from the semiconductor layer 120 side. On the other hand, while the high program voltage Vprog is applied to the selected word line WL-sel, the movement of the electrons to the selected word line WL-sel via the block insulating film 133 from the second electric charge accumulation portion 132b side is not achieved since the voltage Vpass is applied also to the adjacent non-selected word line WL-usel. In the write operation of multi-valued data of, for example, a Multi-Level Cell (MLC), a threshold distribution, that is, a value of stored data is determined by an amount of the electrons accumulated on the first electric charge accumulation portion 132a.

When the data is read, the electric fields between the vicinity of both the ends in the Z direction of the word line WL and the channels can be shielded by the electrons accumulated on the second electric charge accumulation portion 132b. This ensures restrain the channels from turning into a normally on state at both the sides in the gate length direction of the first electric charge accumulation portion 132a, and a read operation with accuracy corresponding to the electric charge amount accumulated on the first electric charge accumulation portion 132a is possible.

### Second Embodiment

FIG. 16 is a flowchart illustrating a write flow of the semiconductor memory device according to a second embodiment.

In the above-described embodiment, as the data erase flow, after the flash erase (S1) that collectively erases the data, the stripe erase (S2) with respect to the odd-numbered memory cells MC-odd and the stripe erase (S3) with respect to the even-numbered memory cells MC-even are performed.

On the other hand, in this embodiment, two stripe erases are performed immediately before the write operation. In view of this, the two stripe erases (S11 and S12) are incorporated in the write flow.

This write flow is executed in a state where the collective erase of the memory block MB has been done. First, the control circuit executes the stripe erase (S11) similar to the above with respect to the odd-numbered memory cells MC-odd. Next, the control circuit executes the stripe erase (S12) similar to the above with respect to the even-numbered memory cells MC-even. Finally, the control circuit executes the writing process (S13) of the data.

With this embodiment, even when it takes a lot of time from the flash erase to the data writing, it is possible to perform writing of the data in a state where the electrons are surely injected into the second electric charge accumulation portion 132b.

[Manufacturing Method]

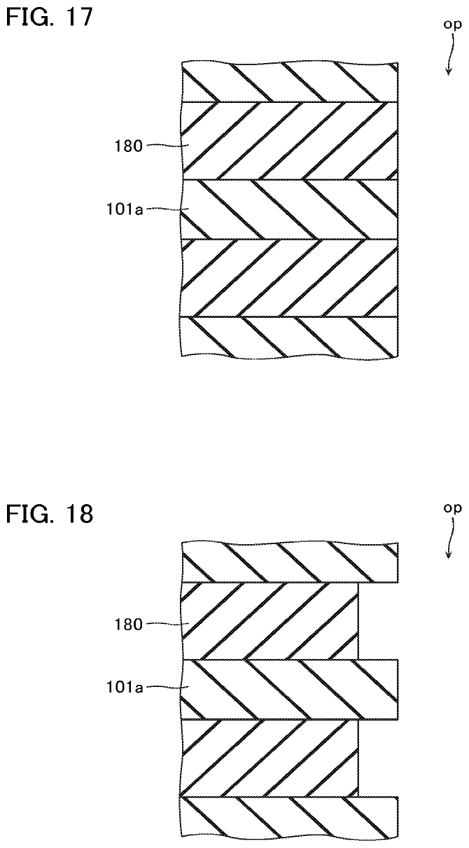

Next, with reference to FIG. 17 to FIG. 24, a method for manufacturing the semiconductor memory device illustrated in FIG. 3 is described. FIG. 17 to FIG. 24 are partial cross-sectional views illustrating the manufacturing process of the semiconductor memory device according to the embodiment in sequence.

As illustrated in FIG. 17, a plurality of insulating layers 101a and a plurality of sacrifice layers 180 are stacked in alternation in the Z direction on the substrate. The insulating layer 101a is made of, for example, silicon oxide (SiO₂). The sacrifice layer 180 is made of, for example, silicon nitride (SiN). This process is performed by a method, such as a Chemical Vapor Deposition (CVD).

Next, an opening op for forming the memory structure 100 is formed on the stacked body made of the insulating layers 101a and the sacrifice layers 180. This process is performed by a method, such as Reactive Ion Etching (RIE).

Next, as illustrated in FIG. 18, recess etching is performed. The recess etching selectively recesses the sacrifice layers 180 of sidewalls facing the opening op backward in the stacked body made of the insulating layers 101a and the sacrifice layers 180. The recess etching is performed by a method, such as wet etching or dry etching.

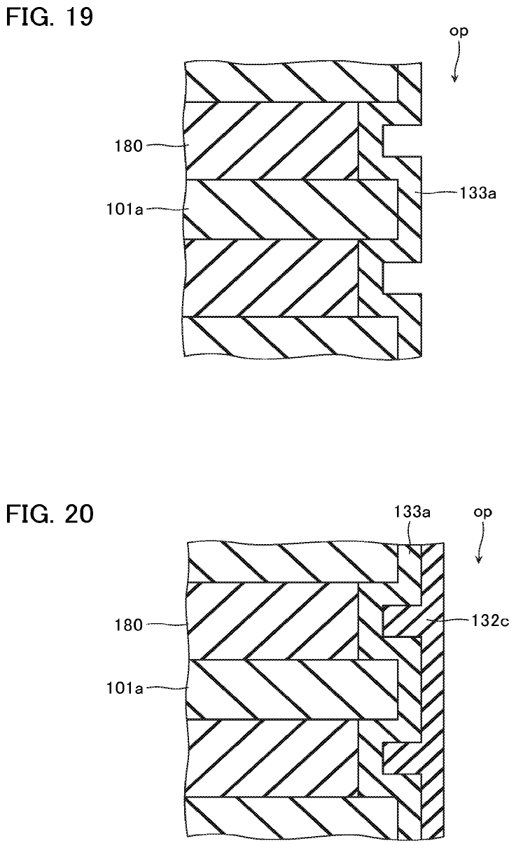

Next, as illustrated in FIG. 19, a block insulating film 133a is formed with a thickness that does not fill a difference in level of the sidewall of the opening op on the sidewall of the opening op. The block insulating film 133a is, for example, made of silicon oxide (SiO₂). This process is performed by a method, such as CVD.

Subsequently, as illustrated in FIG. 20, an electric charge accumulation film 132c is formed on the block insulating film 133a so as to fill the difference in level of the sidewall of the opening op. The electric charge accumulation film 132c is a film of, for example, silicon nitride (SiN) that can accumulate the electric charge. This process is performed by a method, such as CVD.

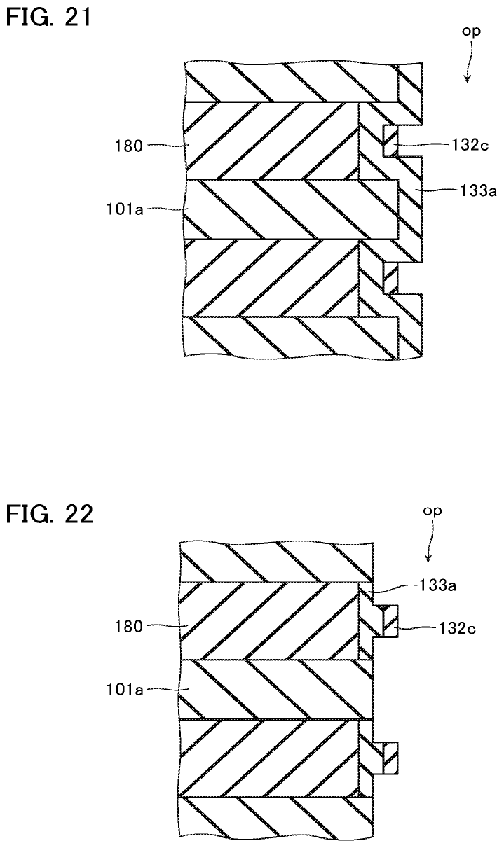

Next, as illustrated in FIG. 21, the recess etching that recesses the electric charge accumulation film 132c backward is performed. The recess etching is performed by a method, such as wet etching or dry etching. This separates the electric charge accumulation film 132c in the stacking direction of the stacked body of the insulating layers 101a and the sacrifice layers 180, and only the electric charge accumulation film 132c in the portions opposed to the center portions in the stacking direction of the sacrifice layers 180 is left.

Subsequently, as illustrated in FIG. 22, the recess etching that selectively recesses the block insulating film 133a and the insulating layer 101a of the sidewall facing the opening op is performed. The recess etching is performed by anisotropic etching, such as wet etching or dry etching. This recess etching recesses surfaces of the insulating layers 101a and the block insulating films 133a facing the opening op backward to a position close to the sacrifice layers 180 with respect to surfaces facing the sacrifice layer 180 of the electric charge accumulation film 132c. That is, on the sidewall facing the opening op, the electric charge accumulation films 132c project with respect to the insulating layers 101a and the block insulating films 133a.

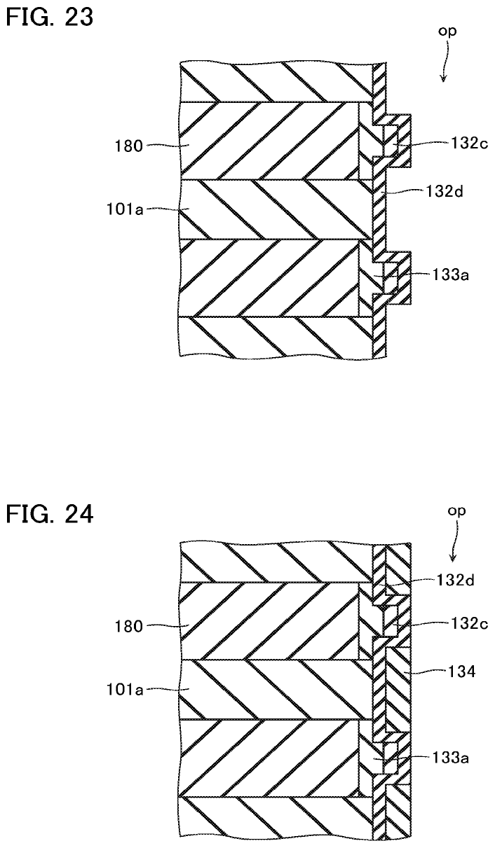

Next, as illustrated in FIG. 23, an electric charge accumulation film 132d is formed along the sidewall of the opening op where the electric charge accumulation films 132c project. The electric charge accumulation film 132d is a film of, for example, silicon nitride (SiN) that ensures accumulation the electric charge. This process is performed by a method, such as CVD.

Next, as illustrated in FIG. 24, the block insulating film 134 is formed on the electric charge accumulation film 132d. This block insulating film 134 is, for example, made of silicon oxide (SiO₂). This process is performed by a method, such as CVD. Afterwards, the recess etching recesses the block insulating film 134 backward to a position approximately on the same surface as the electric charge accumulation film 132d.

Afterwards, the tunnel insulating film 131, the semiconductor layer 120, and the insulating layer 121 are sequentially formed, the sacrifice layers 180 are replaced with the conductive layers 110 via a groove where the insulating portion ST is formed, and thus, the structure illustrated in FIG. 3 can be obtained.

### Third Embodiment

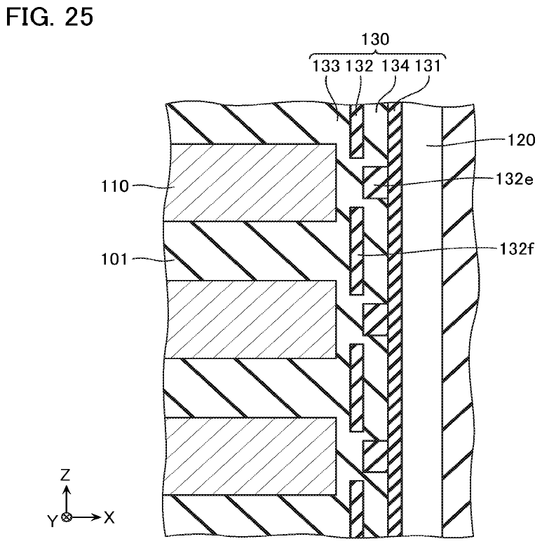

FIG. 25 is a cross-sectional view illustrating a part of a semiconductor memory device according to a third embodiment.

In the first embodiment, the first electric charge accumulation portion 132a and the second electric charge accumulation portion 132b that constitute the electric charge accumulation film 132 are connected in a zigzag manner. On the other hand, in the third embodiment, a first electric charge accumulation portion 132e and a second electric charge accumulation portion 132f constituting the electric charge accumulation film 132 are separated. That is, the first electric charge accumulation portions 132e are disposed in the positions opposed in the X direction to the center portions in the Z direction of the conductive layer 110, and are separated in the Z direction. The second electric charge accumulation portions 132f are disposed in different positions in the X direction and the Z direction from the first electric charge accumulation portions 132e corresponding to positions between the adjacent conductive layers 110, and are separated from one another in the Z direction. The first electric charge accumulation portion 132e is in contact with the tunnel insulating film 131. The second electric charge accumulation portions 132f are disposed at positions close to the conductive layers 110 with respect to the first electric charge accumulation portions 132e.

With such a structure, the electrons accumulated on the second electric charge accumulation portions 132f do not move to the first electric charge accumulation portions 132e, thereby ensuring a further stable performance.

### Fourth Embodiment

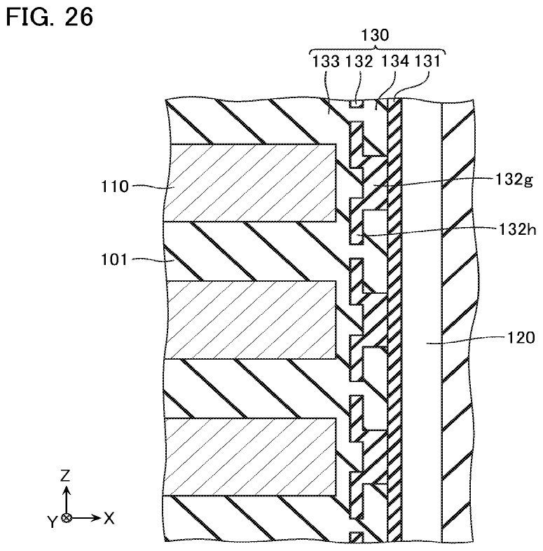

FIG. 26 is a cross-sectional view illustrating a part of a semiconductor memory device according to a fourth embodiment.

In this embodiment, a first electric charge accumulation portion 132g and second electric charge accumulation portions 132h that constitute the electric charge accumulation film 132 are connected. However, the second electric charge accumulation portions 132h are separated in the Z direction at positions corresponding to positions between the adjacent conductive layers 110.

With this structure, the electrons do not move between the adjacent memory cells MC via the second electric charge accumulation portion 132h, thereby ensuring a further stable performance.

[Others]

While the first to fourth embodiments have been described, these embodiments have been presented by way of example only, and are not intended to limit the scope of the inventions. Indeed, these novel embodiments described herein may be embodied in a variety of other forms: furthermore, various omissions, substitutions and changes in the form of the embodiments described herein may be made without departing from the spirit of the inventions. For example, while the respective embodiments described above have shown the examples that form the first electric charge accumulation portions 132a, 132e, and 132g, and the second electric charge accumulation portions 132b, 132f, and 132h with silicon nitride (SiN), either one or both of them can be formed with another material, such as polysilicon, as long as the electric charge accumulation is possible. The accompanying claims and their equivalents are intended to cover such forms or modifications as would fall within the scope and spirit of the inventions.

What is claimed is:

1. A semiconductor memory device comprising:
a substrate; and
a memory cell array that includes a plurality of conductive layers, a semiconductor layer, and an electric charge accumulation portion, the plurality of conductive layers being disposed in a first direction intersecting with a main surface of the substrate, the semiconductor layer extending in the first direction and being opposed to the plurality of conductive layers, the electric charge accumulation portion being disposed between the semiconductor layer and the plurality of conductive layers, the memory cell array including a plurality of memory cells in positions where the plurality of conductive layers and the semiconductor layer are opposed, the plurality of memory cells being connected in series in the first direction to constitute a memory string, wherein
the electric charge accumulation portion includes a plurality of first electric charge accumulation portions opposed to the respective plurality of conductive layers in a second direction along the main surface of the substrate, and a plurality of second electric charge accumulation portions disposed in positions different in the first direction and the second direction from the plurality of first electric charge accumulation portions,
a distance in the second direction between a first electric charge accumulation portion of the plurality of first electric charge accumulation portions and the semiconductor layer is smaller than a distance in the second direction between a second electric charge accumulation portion of the plurality of second electric charge accumulation portions and the semiconductor layer, and
a distance in the second direction between the second electric charge accumulation portion and the plurality of conductive layers is smaller than a distance in the second direction between the first electric charge accumulation portion and the plurality of conductive layers.

2. The semiconductor memory device according to claim 1, wherein
an opposed surface of a conductive layer of the plurality of conductive layers to the electric charge accumulation portion includes first surface portions adjacent to both ends of the opposed surface in the first direction and a second surface portion inside with respect to both the ends of the opposed surface,
a first surface portion of the first surface portions is opposed to the second electric charge accumulation portion, and
the second surface portion is opposed to the first electric charge accumulation portion.

3. The semiconductor memory device according to claim 1, wherein
the first electric charge accumulation portion has a width in the second direction greater than a width in the second direction of the second electric charge accumulation portion.

4. The semiconductor memory device according to claim 1, further comprising
a control circuit that executes an erase operation, a write operation, and a read operation of data with respect to the plurality of memory cells, wherein
the plurality of conductive layers includes a first conductive layer and a second conductive layer adjacent to one another,
the control circuit is capable of executing:
a first erase operation that applies a voltage higher than a first voltage to the second conductive layer while applying the first voltage to the first conductive layer; and
a second erase operation executed after the first erase operation, the second erase operation applying a voltage higher than the first voltage to the first conductive layer while applying the first voltage to the second conductive layer.

5. The semiconductor memory device according to claim 4, wherein
the control circuit:
executes a collective erase operation that applies the first voltage to the plurality of conductive layers; and
executes the first erase operation and the second erase operation after the collective erase operation.

6. A semiconductor memory device comprising:
a substrate; and
a memory cell array that includes a plurality of conductive layers, a semiconductor layer, and an electric charge accumulation portion, the plurality of conductive layers being disposed in a first direction intersecting with a main surface of the substrate, the semiconductor layer extending in the first direction and being opposed to the plurality of conductive layers, the electric charge accumulation portion being disposed between the semiconductor layer and the plurality of conductive layers, the memory cell array including a plurality of memory cells in positions where the plurality of conductive layers and the semiconductor layer are opposed, the plurality of memory cells being connected in series in the first direction to constitute a memory string, wherein
the electric charge accumulation portion opposes to the respective plurality of conductive layers and includes a plurality of first electric charge accumulation portions and a plurality of second electric charge accumulation portions, the plurality of second electric charge accumulation portions being disposed in positions different in the first direction and a second direction along the main surface of the substrate from the plurality of first electric charge accumulation portions,
an opposed surface of a conductive layer of the plurality of conductive layers to the electric charge accumulation portion includes first surface portions adjacent to both ends of the opposed surface in the first direction and a second surface portion inside with respect to both the ends of the opposed surface,
a first surface portion of the first surface portions is opposed to a second electric charge accumulation portion of the plurality of second electric charge accumulation portions in the second direction,
the second surface portion is opposed to a first electric charge accumulation portion of the plurality of first electric charge accumulation portions in the second direction, and
a distance in the second direction between the first surface portion and the second electric charge accumulation portion is smaller than a distance in the second direction between the second surface portion and the first electric charge accumulation portion.

7. The semiconductor memory device according to claim 6, wherein
a distance in the second direction between the first electric charge accumulation portion and the semiconductor layer is smaller than a distance in the second direction between the second electric charge accumulation portion and the semiconductor layer.

8. The semiconductor memory device according to claim 6, wherein
a width in the second direction of the first electric charge accumulation portion is greater than a width in the second direction of the second electric charge accumulation portion.

9. The semiconductor memory device according to claim 6, further comprising
a plurality of insulating layers each disposed between the plurality of conductive layers in the first direction, wherein
the second electric charge accumulation portion is disposed between one of the plurality of insulating layers and the semiconductor layer.

10. The semiconductor memory device according to claim 6, wherein
the first electric charge accumulation portion and the second electric charge accumulation portion are connected to one another.

11. The semiconductor memory device according to claim 6, wherein
the first electric charge accumulation portion and the second electric charge accumulation portion are separately disposed.

12. The semiconductor memory device according to claim 6, wherein
the plurality of conductive layers include a first conductive layer and a second conductive layer adjacent in the first direction, an insulating layer being disposed between the first conductive layer and the second conductive layer to be opposed to the semiconductor layer,
the plurality of second electric charge accumulation portions include:
a first portion opposed to the first conductive layer and the insulating layer in the second direction; and
a second portion opposed to the second conductive layer and the insulating layer in the second direction, and
the first portion and the second portion are separated in the first direction.

13. The semiconductor memory device according to claim 6, further comprising
a control circuit that executes an erase operation, a write operation, and a read operation of data with respect to the plurality of memory cells, wherein
the plurality of conductive layers includes a first conductive layer and a second conductive layer adjacent to one another,
the control circuit is capable of executing:
a first erase operation that applies a voltage higher than a first voltage to the second conductive layer while applying the first voltage to the first conductive layer; and
a second erase operation executed after the first erase operation, the second erase operation applying a voltage higher than the first voltage to the first conductive layer while applying the first voltage to the second conductive layer.

14. The semiconductor memory device according to claim 13, wherein,
the control circuit:
executes a collective erase operation that applies the first voltage to the plurality of conductive layers; and
executes the first erase operation and the second erase operation after the collective erase operation.

15. A semiconductor memory device comprising:
a substrate; and
a memory cell array that includes a plurality of conductive layers, a semiconductor layer, and an electric charge accumulation portion, the plurality of conductive layers being disposed in a first direction intersecting with a main surface of the substrate, the semiconductor layer extending in the first direction and being opposed to the plurality of conductive layers, the electric charge accumulation portion being disposed between the semiconductor layer and the plurality of conductive layers, the memory cell array including a plurality of memory cells in positions where the plurality of conductive layers and the semiconductor layer are opposed, the plurality of memory cells being connected in series in the first direction to constitute a memory string, wherein
the electric charge accumulation portion opposes to the respective plurality of conductive layers and includes a plurality of first electric charge accumulation portions and a plurality of second electric charge accumulation portions, the plurality of second electric charge accumulation portions being disposed in positions different in the first direction and a second direction along the main surface of the substrate from the plurality of first electric charge accumulation portions,
an opposed surface of a conductive layer of the plurality of conductive layers to the electric charge accumulation portion includes first surface portions adjacent to both ends of the opposed surface in the first direction and a second surface portion inside with respect to both the ends of the opposed surface,
a first electric charge accumulation portion of the plurality of first electric charge accumulation portions is opposed to the second surface portion of the conductive layer, and
a second electric charge accumulation portion of the plurality of second electric charge accumulation portions is opposed to a first surface portion of the first surface portions of the conductive layer, the second electric charge accumulation portion extending in the first direction so as to extend beyond a position opposed to an end of the opposed surface from a position opposed to the first surface portion.

16. The semiconductor memory device according to claim 15, wherein
a distance in the second direction between the first electric charge accumulation portion and the semiconductor layer is smaller than a distance in the second direction between the second electric charge accumulation portion and the semiconductor layer, and
a distance in the second direction between the second electric charge accumulation portion and the plurality of conductive layers is smaller than a distance in the second direction between the first electric charge accumulation portion and the plurality of conductive layers.

17. The semiconductor memory device according to claim 15, wherein
a width in the second direction of the first electric charge accumulation portion is greater than a width in the second direction of the second electric charge accumulation portion.

18. The semiconductor memory device according to claim 15, wherein
the plurality of conductive layers include a first conductive layer and a second conductive layer adjacent in the first direction,
the first conductive layer has a third surface portion opposed to the second conductive layer in the first direction, and
the second electric charge accumulation portion opposed to the first surface portion of the first conductive layer extends in the first direction beyond the position opposed to the end of the opposed surface of the first conductive layer so as not to be opposed to the third surface portion of the first conductive layer in the first direction in a portion outside of a position opposed to the first surface portion of the first conductive layer.

19. The semiconductor memory device according to claim 15, further comprising
a control circuit that executes an erase operation, a write operation, and a read operation of data with respect to the plurality of memory cells, wherein
the plurality of conductive layers include a first conductive layer and a second conductive layer adjacent to one another,
the control circuit is capable of executing:
a first erase operation that applies a voltage higher than a first voltage to the second conductive layer while applying the first voltage to the first conductive layer; and
a second erase operation executed after the first erase operation, the second erase operation applying a voltage higher than the first voltage to the first conductive layer while applying the first voltage to the second conductive layer.

20. The semiconductor memory device according to claim 19, wherein
the control circuit:
executes a collective erase operation that applies the first voltage to the plurality of conductive layers; and
executes the first erase operation and the second erase operation after the collective erase operation.
